(19) United States
(12) Patent Application Publication
(10) Pub. No.: US 2024/0429224 A1
(43) Pub. Date: Dec. 26, 2024

(54) SEMICONDUCTOR INTEGRATED CIRCUIT, LAYOUT DESIGN SYSTEM, LAYOUT DESIGNING METHOD, AND NON-TRANSITORY COMPUTER-READABLE STORAGE MEDIUM STORING PROGRAM

(71) Applicant: Kioxia Corporation, Tokyo (JP)

(72) Inventor: Tomoaki YABE, Suginami (JP)

(73) Assignee: Kioxia Corporation, Tokyo (JP)

(21) Appl. No.: 18/744,889

(22) Filed: Jun. 17, 2024

(30) Foreign Application Priority Data
Jun. 20, 2023 (JP) 2023-100900

(51) Int. Cl. H01L 27/02; G06F 30/327; H01L 27/118

(52) U.S. Cl. CPC H01L 27/0207; G06F 30/327; H01L 2027/11812

(57) ABSTRACT

According to one embodiment, a semiconductor integrated circuit includes a first semiconductor layer stacked as a (2n−1)^{th} layer, and a second semiconductor layer stacked as a (2n)^{th} layer. The semiconductor integrated circuit further includes: a first standard cell in which a first conductivity type MOS as a (4i−1)^{th} layer and a second conductivity type MOS as a (4i)^{th} layer share a gate terminal; a second standard cell in which the first conductivity type MOS as a (4i−3)^{th} layer and the second conductivity type MOS as a (4i−2)^{th} layer share a gate terminal; and a third standard cell in which the first conductivity type MOSs as the (4i−3)^{th} layer and as the (4i−1)^{th} layer and the second conductivity type MOSs as the (4i)^{th} layer and as the (4i−2)^{th} layer shares a gate terminal.

### CROSS REFERENCE TO RELATED APPLICATIONS

This application is based upon and claims the benefit of priority from prior Japanese Patent Application No. P2023-100900 filed on Jun. 20, 2023, the entire contents of which are incorporated herein by reference.

### FIELD

Embodiments described herein relate generally to a semiconductor integrated circuit, a layout design system, a layout designing method, and a non-transitory computer-readable storage medium storing a program.

### BACKGROUND

Conventionally, it has been known that, due to efforts for miniaturization of semiconductor devices, NMOS and PMOS transistors are stacked, and semiconductor devices are formed of three-dimensional circuits. However, even when one layer of the NMOS transistor and one layer of the PMOS transistor are stacked on each other, there has been a risk that an element density per substrate unit area may be low.

### BRIEF DESCRIPTION OF THE DRAWINGS

FIG. 1 is a planar pattern configuration diagram illustrating a semiconductor integrated circuit according to an embodiment.

FIG. 2 is a cross-sectional diagram taken in the line A1-A1 of FIG. 1.

FIG. 3A is a planar pattern configuration diagram illustrating a first semiconductor layer.

FIG. 3B is a planar pattern configuration diagram illustrating a first semiconductor layer.

FIG. 3C is a planar pattern configuration diagram illustrating a second semiconductor layer.

FIG. 3D is a planar pattern configuration diagram illustrating a second semiconductor layer.

FIG. 4 is an equivalent circuit diagram illustrating the semiconductor integrated circuit according to the embodiment.

FIG. 5 is a detailed planar pattern configuration diagram illustrating the semiconductor integrated circuit according to the embodiment.

FIG. 6 is a cross-sectional diagram taken in the line A2-A2 of FIG. 5.

FIG. 7 is a cross-sectional diagram taken in the line A3-A3 of FIG. 5.

FIG. 8 is a cross-sectional diagram taken in the line A4-A4 of FIG. 5.

FIG. 9 is a cross-sectional diagram taken in the line A5-A5 of FIG. 5.

FIG. 10 is a cross-sectional diagram taken in the line A6-A6 of FIG. 5.

FIG. 11 is a planar pattern configuration diagram illustrating the semiconductor integrated circuit according to the embodiment, in which a VDD line and a VSS line are omitted.

FIG. 12 is a side view diagram taken in the line A5-A5 and the line A6-A6, in FIG. 11.

FIG. 13 is a schematic diagram illustrating a layout design system using the semiconductor integrated circuit according to embodiment.

FIG. 14 is a block configuration diagram illustrating the layout design system illustrated in FIG. 13.

FIG. 15 is a block configuration diagram of a modified embodiment 1 of the layout design system illustrated in FIG. 13.

FIG. 16 is a block configuration diagram of a modified embodiment 2 of the layout design system illustrated in FIG. 13.

FIG. 17 is a flow chart illustrating a layout designing method using the semiconductor integrated circuit according to the embodiments.

### DETAILED DESCRIPTION

Hereinafter, embodiments will be described with reference to the drawings. A relationship between a thickness and a planar dimension of each component described in the drawings, or a thickness ratio of each component may be different from an actual value. In the embodiments, the vertical direction f the following semiconductor substrate may be different from the vertical direction according to the gravitational acceleration. Moreover, in the embodiments, identical or similar parts are denoted by identical or similar reference numerals, and therefore a description thereof will be appropriately omitted.

The term “connection” used herein includes an electrical connection as well as a physical connection, and also includes a direct connection as well as an indirect connection.

In the following description, an XYZ coordinate system, which is an example of an orthogonal coordinate system, is used. More specifically, a plane parallel to a surface of a substrate constituting a semiconductor integrated circuit is defined as an X-Y plane and a direction orthogonal to the X-Y plane is defined as a Z direction. Moreover, the X-axis and the Y-axis are two directions orthogonal to each other in the X-Y plane. It is to be noted that these directions are merely examples.

It can be changed as appropriate on an arrangement of a pattern. Moreover, the substrate may include an insulator substrate, a semiconductor substrate, substrate formed by embedding an electrode layer into an insulator substrate, and the like. Furthermore, the substrate may be a substrate formed by embedding therein a semiconductor element including an N-channel Metal Oxide Semiconductor (MOS) field effect transistor, a P-channel MOS field effect transistor, or a Complementary MOS (CMOS) field effect transistor.

Certain embodiments provide a semiconductor integrated circuit with efficiently high logic density by using two types of standard cells with different numbers of layers, a layout design system for such a semiconductor integrated circuit, a layout designing method, and a non-transitory computer-readable storage medium storing a program.

In general, according to the embodiment, a semiconductor integrated circuit includes: a first semiconductor layer including a first source region, a first drain region, and a first channel region; a second semiconductor layer including a second source region, a second drain region, and a second channel region; a gate electrode formed to cover the first channel region and the second channel region with a gate insulating film interposed therebetween; and a first CMOS circuit and a second CMOS circuit each formed of a combination of a first conductive type MOS including the first semiconductor layer and a second conductive type MOS including the second semiconductor layer. The first semiconductor layer is stacked as a (2n−1)^{th} layer, and the second semiconductor layer is stacked as a (2n)^{th} layer (where 1≤n≤N, N≥2, and n and N are integers). For a certain i (where 1≤i≤N), in the first CMOS circuit, the gate electrode is electrically connected in common to at least the first conductive type MOS of the first semiconductor layer as a (2i−1)^{th} layer and the second conductive type MOS of the second semiconductor layer as a (2i)^{th} layer. Moreover, in the second CMOS circuit, the gate electrode is electrically connected in common with at least the second conductive type MOS of the second semiconductor layer as the (2i)^{th} layer and the first conductive type MOS of the first semiconductor layer as a (2i+1)^{th} layer. The above-described semiconductor integrated circuit further includes: for a certain i (where 1≤i≤N), a first standard cell in which the first conductivity type MOS as a (4i−1)^{th} layer and the second conductivity type MOS as a (4i)^{th} layer share a gate terminal; a second standard cell in which the first conductivity type MOS of a (4i−3)^{th} layer and the second conductivity type MOS as a (4i−2)^{th} layer share a gate terminal; and a third standard cell in which the first conductivity type MOSs as the (4i−3)^{th} layer and as the (4i−1)^{th} layer and the second conductivity type MOSs as the (4i)^{th} layer and as the (4i−2)^{th} layer shares a gate terminal.

Hereinafter, semiconductor integrated circuits, layout design systems, layout designing methods, and non-transitory computer-readable storage medium storing program disclosed herein will be described with reference to the drawings.

### (Configuration of Semiconductor Integrated Circuit)

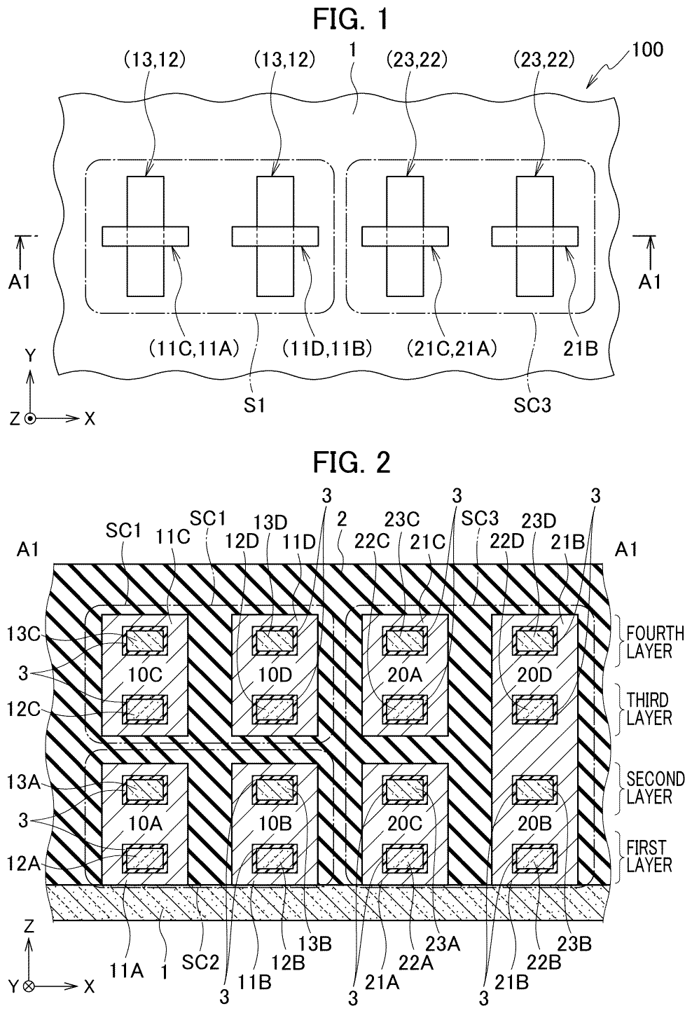

FIG. 1 is a planar pattern configuration diagram Illustrating a semiconductor integrated circuit 100 according to an embodiment. FIG. 2 is a cross-sectional diagram taken in the line A1-A1 of FIG. 1. Illustration of an interlayer insulating film 2 is omitted in FIG. 1. The semiconductor integrated circuit 100 according to the embodiment may include a substrate 1 and an interlayer insulating film 2. In FIGS. 1 and 2, an arrangement direction of gate electrodes 11A, 11B, 21A, and 21B is an X direction. An arrangement direction of gate electrodes 11C, 11D, 21C, and 21B is also the X direction. In FIGS. 1 and 2, an extending direction of first semiconductor layers 12 and 22 is a Y direction. An extending direction of second semiconductor layers 13 and 23 is also the Y direction. A plane parallel to the substrate 1 defined by the X direction and the Y direction is an XY plane, and a direction perpendicular to the XY plane is a Z direction.

As illustrated in FIGS. 1 and 2, the semiconductor integrated circuit 100 according to the embodiment includes a first semiconductor layer (12 and 22), a second semiconductor layer (13 and 23), and a gate electrode (11A, 11B, 11C, 11D, 21A, 21B, and 21C). The semiconductor integrated circuit 100 according to the embodiment further includes a first Complementary MOS (CMOS) circuit 10 (10A, 10B, 10C, and 10D) and a second CMOS circuit 20 (20A, 20B, and 20C), which are formed of a combination of a first conductivity type Metal Oxide Semiconductor (MOS) and a second conductivity type MOS.

As illustrated in FIG. 2, the first CMOS circuit (10C and 10D) forms a first standard cell SC1 (SC Type A), and the first CMOS circuit (10A and 10B) forms a second standard cell SC2 (SC Type A). The second CMOS circuit 20 (20A, 20B, and 20C) forms a third standard cell SC3 (SC Type B). The first standard cell SC1 is stacked in the Z direction above the second standard cell SC2.

The third standard cell SC3 (SC Type B) includes the second CMOS circuit 20A, the second CMOS circuit 20C stacked in the Z direction above the second CMOS circuit 20A, the second CMOS circuit 20B, and a second CMOS circuit 20D stacked in the Z direction above the second CMOS circuit 20B. Herein, the second CMOS circuit 20B and the second CMOS circuit 20D share the gate electrode 21B.

The first standard cell SC1 can drive a relatively small-capacity capacitor C1. The second standard cell SC2 can drive a relatively small-capacity capacitor C2. The third standard cell SC3 can drive a relatively large-capacity capacitor C3. Herein, the capacitors C1 and C2 have smaller capacity values than that of the capacitor C3. In the following descriptions, a first semiconductor layer (12A, 12B, 22A, and 22B) as a first layer and a first semiconductor layer (12C, 12D, 22C, and 22D) as a third layer illustrated in FIG. 2 are collectively referred to as the first semiconductor layer (12 and 22). Moreover, a second semiconductor layer (13A, 13B, 23A, and 23B) as a second layer and a second semiconductor layer (13C, 13D, 23C, and 23D) of a fourth layer illustrated in FIG. 2 are also collectively referred to as the second semiconductor layer (13 and 23).

As illustrated in FIG. 2, the interlayer insulating film 2 is disposed on the substrate 1. The interlayer insulating film 2 is disposed so as to cover the gate electrode (11A, 11B, 11C, 11D, 21A, 21B, and 21C), the first semiconductor layer (12 and 22), and the second semiconductor layer (13 and 23).

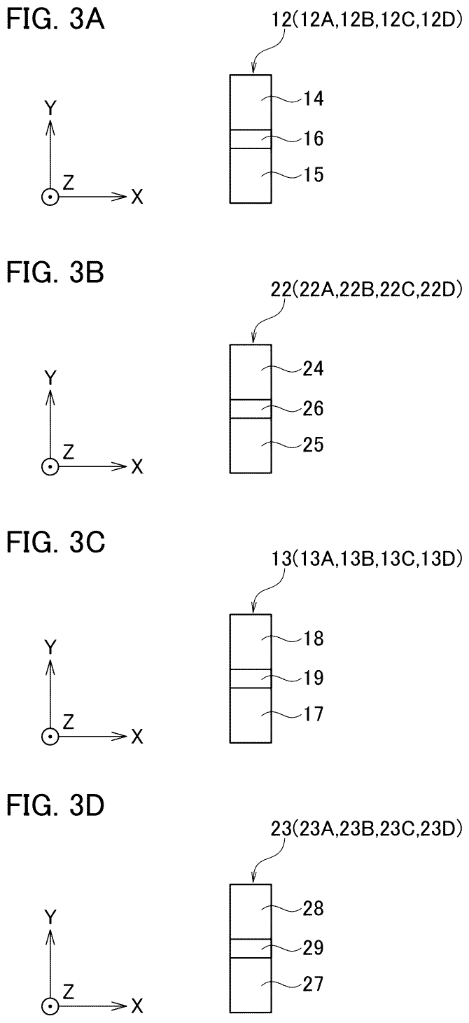

FIG. 3A is a planar pattern configuration diagram illustrating the first semiconductor layer 12 (12A, 12B, 12C, and 12D). FIG. 3B is a planar pattern configuration diagram illustrating the first semiconductor layer 22 (22A, 22B, 22C, and 22D). FIG. 3C is a planar pattern configuration diagram illustrating the second semiconductor layer 13 (13A, 13B, 13C, and 13D). FIG. 3D is a planar pattern configuration diagram illustrating the second semiconductor layer 23 (23A, 23B, 23C, and 23D).

As illustrated in FIGS. 3A and 3B, the first semiconductor layer 12 and the first semiconductor layer 22 each include a source region (14 and 24), a drain region (15 and 25), and a channel region (16 and 26).

As illustrated in FIGS. 3C and 3D, the second semiconductor layer 13 and the second semiconductor layer 23 each include a source region (17 and 27), a drain region (18 and 28), and a channel region (19 and 29).

As illustrated in FIG. 2, the first semiconductor layer (12A, 12B, 22A, and 22B) is disposed, for example, as a first layer stacked in the Z direction vertical to a front surface of the substrate 1. Moreover, the first semiconductor layer (12C, 12D, 22C, and 22D) is disposed, for example, as a third layer stacked in the Z direction vertical to the front surface of the substrate 1. Namely, the first semiconductor layer (12 and 22) is stacked as the (2n−1)^{th} layer (where 1≤n≤N, N≥2, n and N are integers).

As illustrated in FIG. 2, the second semiconductor layer (13A, 13B, 23A, and 23B) is disposed, for example, as a second layer stacked in the Z direction vertical to the front surface of the substrate 1. Moreover, the second semiconductor layer (13C, 13D, 23C, and 23D) is disposed, for example, as a fourth layer stacked in the Z direction vertical to the front surface of the substrate 1. Namely, the second semiconductor layer (13 and 23) is stacked as the (2n)^{th} layer (where 1≤n≤N, N≥2, n and N are integers). It is to be noted that, in FIG. 2, there are four stacked layers including the first semiconductor layer (12 and 22) and the second semiconductor layer (13 and 23), but there may be four or more stacked layers.

The first conductivity type MOS includes the first semiconductor layer (12 and 22). Specifically, the first conductivity type MOS may be, for example, a P-channel MOS (PMOS).

The second conductivity type MOS includes the second semiconductor layer (13 and 23). Specifically, the second conductivity type MOS may be, for example, an N-channel MOS (NMOS).

As illustrated in FIG. 2, the gate electrode (11A, 11B, 11C, 11D, 21A, 21B, and 21C) is disposed on the substrate 1. The gate electrode (11A, 11B, 11C, 11D, 21A, 21B, and 21C) is formed so as to cover the channel region (i.e., first channel region) (16 and 26) and the channel region (i.e., second channel region) (19 and 29) with a gate insulating film 3 interposed therebetween. Thus, a structure in which the gate electrode covers a periphery of the channel region with the gate insulating film interposed therebetween has a so-called Surrounding Gate Transistor (SGT) structure. The SGT structure is also referred to as a gate all-around structure.

Specifically, a gate electrode 11A is formed so as to cover a channel region 16 of a first semiconductor layer 12A and a channel region 19 of a second semiconductor layer 13A. A gate electrode 11B is formed so as to cover a channel region 16 of a first semiconductor layer 12B and a channel region 19 of a second semiconductor layer 13B.

A gate electrode 11C is formed so as to cover a channel region 16 of a first semiconductor layer 12C and a channel region 19 of a second semiconductor layer 13C. A gate electrode 11D is formed so as to cover a channel region 16 of a first semiconductor layer 12D and a channel region 19 of a second semiconductor layer 13D.

A gate electrode 21A is formed as to cover a channel region 16 of a first semiconductor layer 22A and a channel region 19 of a second semiconductor layer 23A. A gate electrode 21C is formed so as to cover a channel region 26 of a first semiconductor layer 22C and a channel region 29 of a second semiconductor layer 23C.

A gate electrode 21B is formed as to cover a channel region 26 of a first semiconductor layer (22B and 22D) and a channel region 29 of a second semiconductor layer (23B and 23D).

In the first standard cell SC1, the gate electrode 11C and the gate electrode 11D are disposed to be separated from each other.

In the second standard cell SC2, the gate electrode 11A and the gate electrode 11B are disposed to be separated from each other.

In the third standard cell SC3, the gate electrode 21A, the gate electrode 21B, and the gate electrode 21C are disposed to be separated from one another.

The first CMOS circuit 10 (10A, 10B, 10C, and 10D) and the second CMOS circuit 20 (20A, 20B, 20C, and 20D) are each formed of a combination of the first conductivity type MOS and the second conductivity type MOS.

The first CMOS circuit 10 includes the gate electrode (11A, 11B, 11C, and 11D). In the first CMOS circuit 10, for a certain i (where 1≤i≤N), the gate electrode (11A, 11B, 11C, and 11D) is electrically connected in common to at least the first conductivity type MOS of the first semiconductor layer 12 as a (2i−1)^{th} layer (i.e., 1st, 3rd, 5th, . . . (2i−1)^{th} layer) and the second conductivity type MOS of the second semiconductor layer 13 as a (2i)^{th} layer (i.e., 2^{nd}, 4^{th}, 6^{th}, . . . (2i)^{th} layer).

Specifically, in the first CMOS circuit 10, for example, the gate electrode 11A is electrically connected in common to the PMOS, which is the first conductivity type MOS of the first semiconductor layer 12A, as the first layer and the NMOS, which is the second conductivity type MOS of the second semiconductor layer 13A, as the second layer.

For example, the gate electrode 11B is electrically connected in common to the PMOS, which is the first conductivity type MOS of the first semiconductor layer 12B, as the first layer and the NMOS, which is the second conductivity type MOS of the second semiconductor layer 13B, as the second layer.

For example, the gate electrode 11C is electrically connected in common to the PMOS, which is the first conductivity type MOS of the first semiconductor layer 12C, as the third layer and the NMOS, which is the second conductivity type MOS of the second semiconductor layer 13C, as the fourth layer.

For example, in the first CMOS circuit 10, for example, the gate electrode 11D is electrically connected in common to the PMOS, which is the first conductivity type MOS of the first semiconductor layer 12D, as the third layer and the NMOS, which is the second conductivity type MOS of the second semiconductor layer 13D, as the fourth layer.

The second CMOS circuit 20 includes the gate electrode (21A, 21B, and 21C). In the second CMOS circuit 20, for example, the gate electrode 21A is electrically connected in common to the PMOS, which is the first conductivity type MOS of the first semiconductor layer 22A, as the first layer and the NMOS, which is the second conductivity type MOS of the second semiconductor layer 23A, as the second layer.

For example, the gate electrode 21C is electrically connected in common to the PMOS, which is the first conductivity type MOS of the first semiconductor layer 22C, as the third layer and the NMOS, which is the second conductivity type MOS of the second semiconductor layer 23C, as the fourth layer.

Moreover, in the second CMOS circuit 20, for a certain i (where 1≤i≤N), the gate electrode 21B is electrically connected in common to at least the second conductivity type MOS of the second semiconductor layer 23 as the (2i)^{th} layer and the first conductivity type MOS of the first semiconductor layer 22 as the (2i+1)^{th} layer (i.e., 3^{rd}, 5^{th}, 7^{th}, . . . (2i+1)^{th} layer). Specifically, in the second CMOS circuit 20, for example, the gate electrode 21B is electrically connected in common to the NMOS, which is the second conductivity type MOS of the second semiconductor layer 23B, as the second layer and the PMOS, which is the first conductivity type MOS of the first semiconductor layer 22D, as the third layer. Furthermore, for example, the gate electrode 21B may be electrically connected in common to the PMOS, which is the first conductivity type MOS of the first semiconductor layer 22B, as the first layer and the NMOS, which is the second conductivity type MOS of the second semiconductor layer 23D, as the fourth layer.

The semiconductor integrated circuit 100 according to the embodiment includes: for a certain i (where 1≤i≤N), a first standard cell SC1 in which the first conductivity type MOS as a (4i−1)^{th} layer and the second conductivity type MOS as a (4i)^{th} layer share a gate terminal; a first standard cell SC2 in which the second conductivity type MOS of a (4i−3)^{th} layer and the second conductivity type MOS as a (4i−2)^{th} layer share a gate terminal; and a third standard cell SC3 in which the first conductivity type MOSs as the (4i−3)^{th} layer and as the (4i−1)^{th} layer and the second conductivity type MOSs as the (4i)^{th} layer and as the (4i−2)^{th} layer shares a gate terminal.

The semiconductor integrated circuits 100 according to the embodiment further includes a plurality of first standard cells SC1 and second standard cells SC2, and at least some of the first standard cells SC1 are disposed to be placed on at least some of the second standard cells SC2.

A capacity of a signal line driven by the first standard cell SC1 and the second standard cell SC2 is lower than a capacity of a signal line driven by the third standard cell SC3.

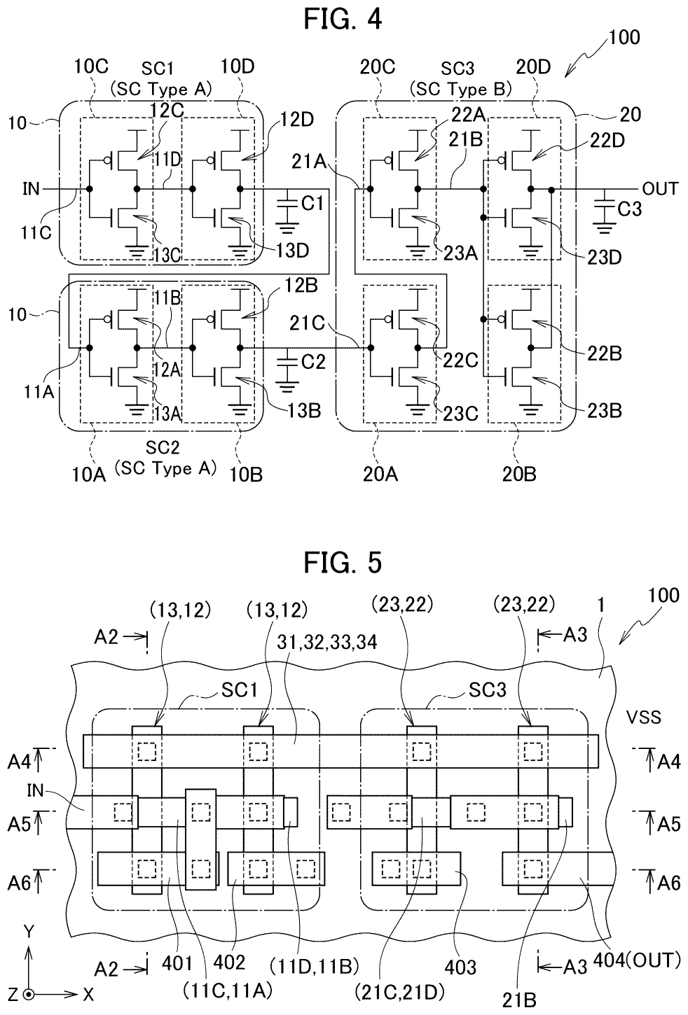

Next, an equivalent circuit of the semiconductor integrated circuit 100 will be described with reference to FIG. 4. The equivalent circuit of the semiconductor integrated circuit 100 is illustrated with the first CMOS circuit 10 (10A, 10B, 10C, and 10D) and the second CMOS circuit 20 (20A, 20B, and 20C), as illustrated in FIG. 4. A connecting relationship between the first CMOS circuit 10 (10A, 10B, 10C, and 10D) and the second CMOS circuit 20 (20A, 20B, and 20C) will be described below.

In the following description, a circuit structure including the first semiconductor layer 12A and the second semiconductor layer 13A is also referred to as a first circuit structure. A circuit structure including the first semiconductor layer 12B and the second semiconductor layer 13B is also referred to as a second circuit structure. A circuit structure including the first semiconductor layer 12C and the second semiconductor layer 13C is also referred to as a third circuit structure. A circuit structure including the first semiconductor layer 12D and the second semiconductor layer 13D is also referred to as a fourth circuit structure. A circuit structure including the first semiconductor layer 22A and the second semiconductor layer 23A is also referred to as a fifth circuit structure. A circuit structure including the first semiconductor layer 22B and the second semiconductor layer 23B is also referred to as a sixth circuit structure. A circuit structure including the first semiconductor layer 22C and the second semiconductor layer 23C is also referred to as a seventh circuit structure. A circuit structure including the first semiconductor layer 22D and the second semiconductor layer 23D is also referred to as a eighth circuit structure.

The first CMOS circuit 10A can be represented, for example, as the first circuit structure in which the gate electrode 11A is commonly connected to the PMOS which is the first conductivity type MOS including the first semiconductor layer 12A as the first layer, and the NMOS which is the second conductivity type MOS including the second semiconductor layer 13A as the second layer. Moreover, the first CMOS circuit 10B can be represented, for example, as the second circuit structure in which the gate electrode 11B is commonly connected to the PMOS which is the first conductivity type MOS including the first semiconductor layer 12B as the first layer and the NMOS which is the second conductivity type MOS including the second semiconductor layer 13B as the second layer.

Similarly, the first CMOS circuit 10C can be represented, for example, as the third circuit structure in which the gate electrode 11C is commonly connected to the PMOS which is the first conductivity type MOS including the first semiconductor layer 12C as the third layer and the NMOS which is the second conductivity type MOS including the second semiconductor layer 13C as the fourth layer. Moreover, the first CMOS circuit 10D can be represented, for example, as the fourth circuit structure in which the gate electrode 11D is electrically connected in common to the PMOS which is the first conductivity type MOS including the first semiconductor layer 12D as the third layer and the NMOS which is the second conductivity type MOS including the second semiconductor layer 13D as the fourth layer.

The second CMOS circuit 20A can be represented, for example, as the fifth circuit structure in which the gate electrode 21A is electrically connected in common to the PMOS which is the first conductivity type MOS including the first semiconductor layer 22A as the first layer and the NMOS which is the second conductivity type MOS including the second semiconductor layer 23A as the second layer. Moreover, the second CMOS circuit 20B can be represented, for example, as the sixth circuit structure which the gate electrode 21B is electrically connected in common to the PMOS which is the first conductivity type MOS including the first semiconductor layer 22B as the first layer and the NMOS which is the second conductivity type MOS including the second semiconductor layer 23B as the second layer.

Moreover, the second CMOS circuit 20C can be represented, for example, as the seventh circuit structure in which the gate electrode 21C is electrically connected in common to the PMOS which is the first conductivity type MOS including the first semiconductor layer 22C as the first layer and the NMOS which is the second conductivity type MOS including the second semiconductor layer 23C as the second layer.

Moreover, the second CMOS circuit 20D can be represented, for example, as the eighth circuit structure which the gate electrode 21C is electrically connected in common to the PMOS which is the first conductivity type MOS including the first semiconductor layer 22D as the first layer and the NMOS which is the second conductivity type MOS including the second semiconductor layer 23D as the second layer. Furthermore, the sixth circuit structure and the eighth circuit structure can be represented as a circuit structure in which the gate electrode 21B is electrically connected in common.

As illustrated in FIG. 4, the semiconductor integrated circuit 100 according to the embodiment can be formed including the standard cell SC1 (SC Type A), the standard cell SC2 (SC Type A), and the standard cell SC3 (SC Type B) as a basic unit. In the semiconductor integrated circuit 100, a plurality of CMOS circuits each having, as a basic unit, the standard cell SC1, the standard cell SC2, and the standard cell SC3 are arranged in the XY directions, and are further arranged as a plurality of layers in the Z direction. The semiconductor integrated circuit 100 according to the embodiment can provide a semiconductor integrated circuit with efficiently high logic density by using two types of standard cells with different numbers of layers.

### (Detailed Planar Pattern Configuration)

FIG. 5 is a detailed planar pattern configuration diagram illustrating the semiconductor integrated circuit 100 according to the embodiment. Illustration of the interlayer insulating film 2 is omitted in FIG. 5. As illustrated in FIG. 5, the semiconductor integrated circuit 100 includes a power supply wiring layer (31, 32, 33, and 34), the gate electrode (11C and 11A), the gate electrode (11D and 11B), the gate electrode (21C and 21D), the gate electrode 21B, and a signal wiring layer (401, 402, 403, and 404).

### (Cross-Sectional Structure: A2-A2)

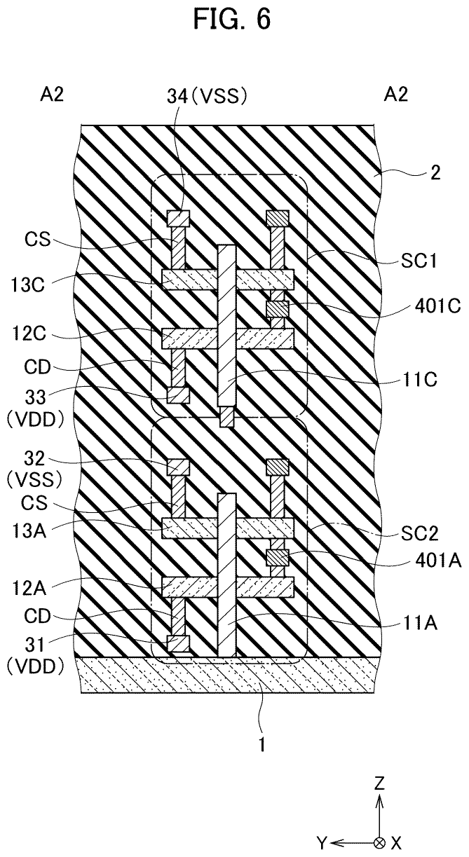

FIG. 6 is a cross-sectional diagram taken in the line A2-A2 of FIG. 5. As illustrated in FIG. 6, the standard cell SC1 (SC Type A) is disposed on the standard cell SC2 (SC Type A). The second semiconductor layer (13A and 13C) as the second layer is disposed above the first semiconductor layer (12A and 12C) as the first layer. The first semiconductor layer 12A and the second semiconductor layer 13A pass through the gate electrode 11A. The first semiconductor layer 12C and the second semiconductor layer 13C pass through the gate electrode 11C.

The first power supply wiring layer 31 is disposed, for example, below (i.e., in the minus Z direction of) the source region 14A of the first semiconductor layer 12A. Moreover, the first power supply wiring layer 33 is disposed, for example, below (i.e., in the minus Z direction of) the source region 14C of the first semiconductor layer 12C. The first power supply wiring layer (31 and 33) may be, for example, a VDD wiring.

The second power supply wiring layer 32 is disposed, for example, above (i.e., in the Z direction of) the source region 17A of the second semiconductor layer 13A. Moreover, the second power supply wiring layer 34 is disposed, for example, above (i.e., in the Z direction of) the source region 17C of the second semiconductor layer 13C. The second power supply wiring layer (32 and 34) may be, for example, a VSS wiring.

The drain region 15A of the first semiconductor layer 12A is connected to the drain region 18A of the second semiconductor layer 13A. The drain region 18A of the second semiconductor layer 13A is connected to the signal wiring layer 401A. The drain region 15C of the first semiconductor layer 12C is connected to the drain region 18C of the second semiconductor layer 13C. The drain region 18C of the second semiconductor layer 13C is connected to the signal wiring layer 401C.

### (Cross-Sectional Structure: A3-A3)

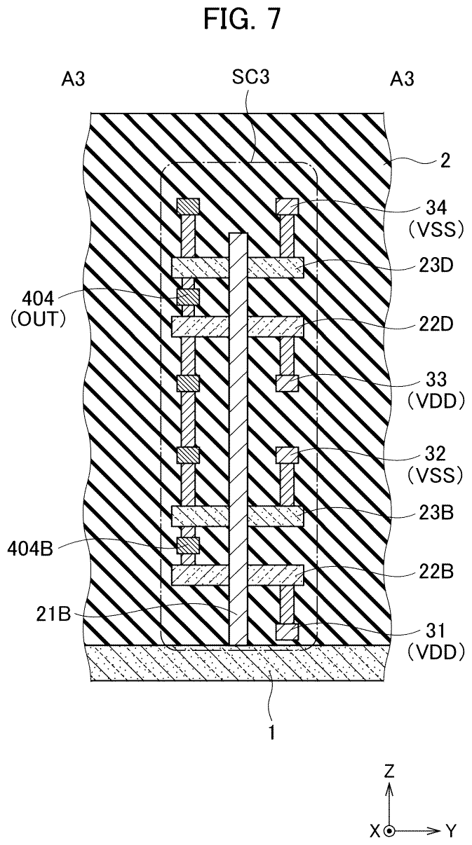

FIG. 7 is a cross-sectional diagram taken in the line A3-A3 of FIG. 5. As illustrated in FIG. 7, the standard cell SC3 (SC Type B) is disposed. The second semiconductor layer (23B and 23D) is disposed above (i.e., in the Z direction of) the first semiconductor layer (22B, 22D). The first semiconductor layer (22B and 22D) and the second semiconductor layer (23B and 23D) pass through the gate electrode 21B.

The first power supply wiring layer 31 is disposed, for example, below (i.e., in the minus Z direction of) the source region 24B of the first semiconductor layer 22B. Moreover, the first power supply wiring layer 33 is disposed, for example, below (i.e., in the minus Z direction of) the source region 24D of the first semiconductor layer 22D. The first power supply wiring layer (31 and 33) may be, for example, a VDD wiring.

The second power supply wiring layer 32 is disposed, for example, above (i.e., in the Z direction of) the source region 27B of the second semiconductor layer 23B. Moreover, the second power supply wiring layer 34 is disposed, for example, above (i.e., in the Z direction of) the source region 27D of the second semiconductor layer 23D. The second power supply wiring layer (32 and 34) may be, for example, a VSS wiring.

The drain region 25B of the first semiconductor layer 22B is connected to the drain region 28B of the second semiconductor layer 23B. The drain region 28B of the second semiconductor layer 23B is connected to the signal wiring layer 404B. The drain region 25D of the first semiconductor layer 22D is connected to the drain region 28D of the second semiconductor layer 23D. The drain region 28D of the second semiconductor layer 23D is connected to the signal wiring layer 404.

Accordingly, the drain region 25B of the first semiconductor layer 22B, the signal wiring layer 404B, the drain region 28B of the second semiconductor layer 23B, the drain region 25D of the first semiconductor layer 22D, the signal wiring layer 404, and the drain region 28D of the second semiconductor layer 23D are electrically connected in common. An output OUT is obtained from the signal wiring layer 404.

### (Cross-Sectional Structure: A4-A4)

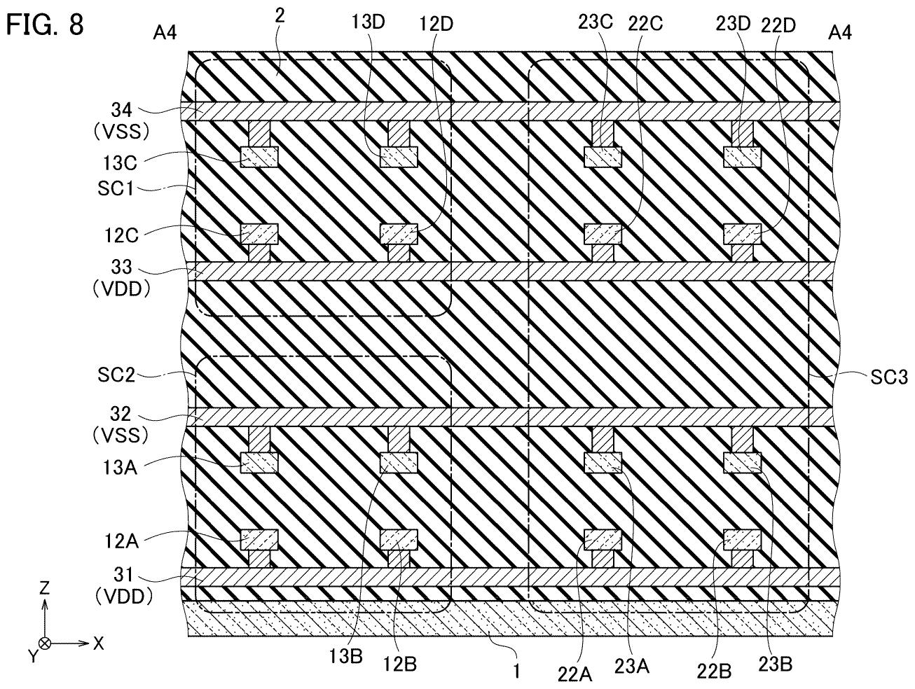

FIG. 8 is a cross-sectional diagram taken in the line A4-A4 of FIG. 5. As illustrated in FIG. 8, the standard cell SC1 is disposed above (i.e., in the plus Z direction of) the standard cell SC2. The standard cell SC3 is disposed in the X direction adjacent to the standard cell SC1 and the standard cell SC2. As illustrated in FIG. 8, the power supply wiring layer (31 and 33) is disposed, for example, below (i.e., in the minus Z direction of) the the first semiconductor layer (12 and 22). A direction in which the first semiconductor layer (12 and 22) extends is the Y direction, and a direction in which the power supply wiring layer (31 and 33) extends is the X direction. Specifically, the power supply wiring layer 31 is disposed, for example, below (i.e., in the minus Z direction of) the source region (14 and 24) of the first semiconductor layer (12A, 12B, 22A, and 22B). The power supply wiring layer 33 is disposed, for example, below (i.e., in the minus Z direction of) the source region (14 and 24) of the first semiconductor layer (12C, 12D, 22C, and 22D). The power supply wiring layer (31 and 33) may be, for example, a VDD wiring.

The power supply wiring layer (32 and 34) is disposed, for example, above (i.e., in the plus Z direction of) the second semiconductor layer (13 and 23). A direction in which the second semiconductor layer (13 and 23) extends is the Y direction, and a direction in which the power supply wiring layer (32 and 34) extends is the X direction. Specifically, the power supply wiring layer 32 is disposed, for example, above (i.e., in the plus Z direction of) the drain region (18 and 28) of the second semiconductor layer (13A, 13B, 23A, and 23B). Moreover, the power supply wiring layer 34 is disposed, for example, above (i.e., in the plus Z direction of) the drain region (18 and 28) of the second semiconductor layer (13C, 13D, 23C, and 23D). The power supply wiring layer (32 and 34) may be, for example, a VSS wiring.

### (Cross-Sectional Structure: A5-A5)

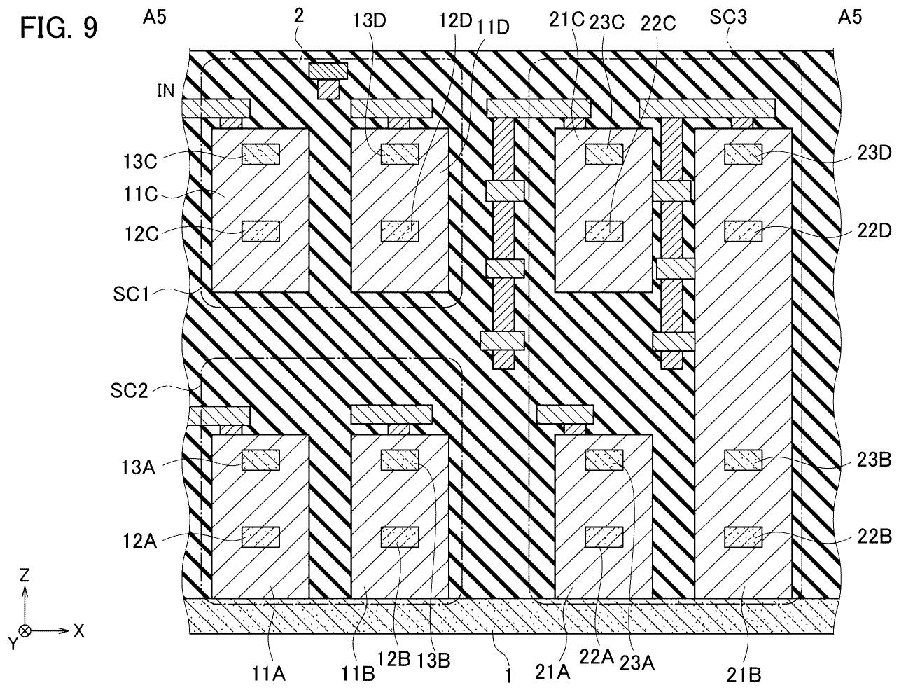

FIG. 9 is a cross-sectional diagram taken in the line A5-A5 of FIG. 5. In FIG. 9, illustration of the gate insulating film 3 illustrated in FIG. 3 is omitted. As illustrated in FIG. 9, the standard cell SC1 is disposed in the Z direction on the standard cell SC2. The standard cell SC3 is disposed in the X direction adjacent to the standard cell SC1 and the standard cell SC2. The standard cell SC1 includes the gate electrodes 11C and 11D, and the standard cell SC2 includes gate electrodes 11A and 11B. The standard cell SC3 includes gate electrodes 21A, 21B, and 21C. The second semiconductor layer (13A, 13B, 23A, and 23B) is disposed above (i.e., in the plus Z direction of) the first semiconductor layer (12A, 12B, 22A, and 22B). The second semiconductor layer (13C, 13D, 23C, and 23D) is disposed above (i.e., in the plus Z direction of) the first semiconductor layer (12C, 12D, 22C, and 22D).

The first semiconductor layer (12A, 12B, 22A, and 22B) and the second semiconductor layer (13A, 13B, 23A, and 23B) pass through the gate electrode (11A, 11B, 21A, and 21B). Similarly, the first semiconductor layer (12C, 12D, 22C, and 22D) and the second semiconductor layer (13C, 13D, 23C, and 23D) pass through the gate electrode (11C, 11D, 21C, and 21B). An input IN is connected to the gate electrode 11C.

### (Cross-Sectional Structure: A6-A6)

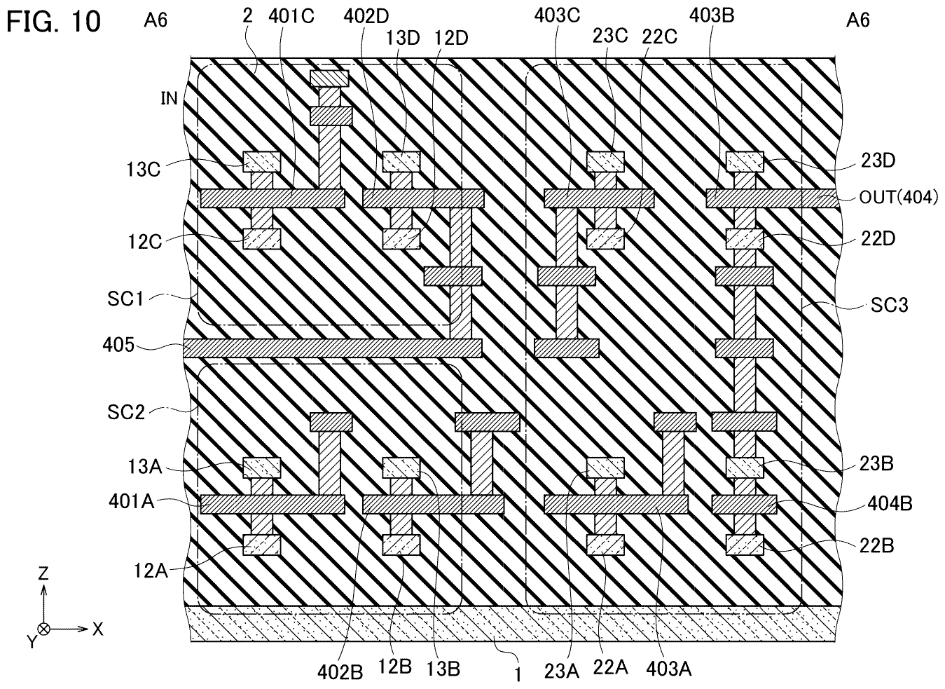

FIG. 10 is a cross-sectional diagram taken in the line A6-A6 of FIG. 5. As illustrated in FIG. 10, in the standard cell SC1, an output of the first CMOS circuit 10C is connected to the signal wiring layer 401C, and an output of the first CMOS circuit 10D is connected to the signal wiring layer 402D. The signal wiring layer 402D is connected to the signal wiring layer 405, and the signal wiring layer 405 is connected to the gate electrode 11A of the first CMOS circuit 10A.

Moreover, in the standard cell SC2, an output of the first CMOS circuit 10A is connected to the signal wiring layer 401A, and an output of the first CMOS circuit 10B is connected to the signal wiring layer 402B.

Moreover, in the standard cell SC3, an output of the second CMOS circuit 20A is connected to the signal wiring layer 403A, an output of the second CMOS circuit 20B is connected to the signal wiring layer 404B, an output of the second CMOS circuit 20C is connected to the signal wiring layer 403C, and an output of the second CMOS circuit 20D is connected to the signal wiring layer 404. The output OUT is obtained from the signal wiring layer 404.

### (Side Surface Structure: (A5-A5)+(A6-A6))

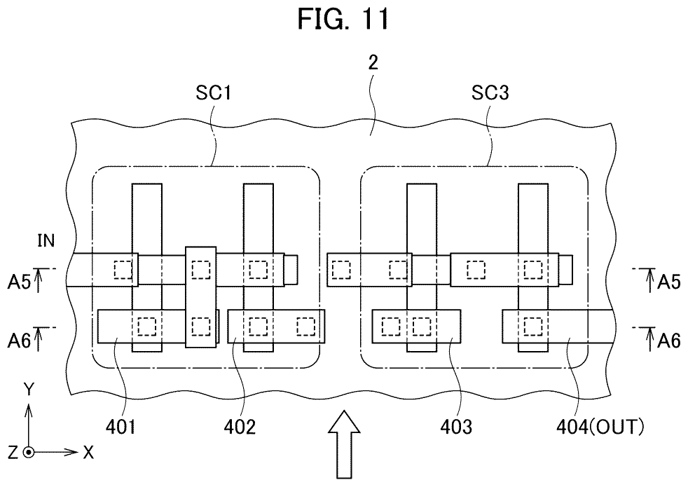

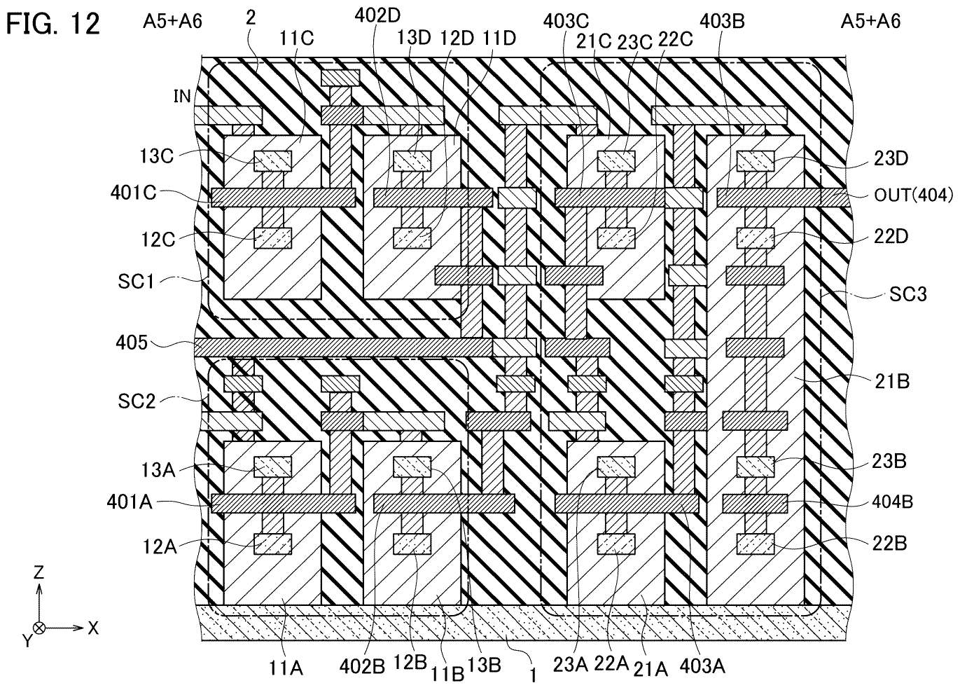

FIG. 11 is a diagram obtained from FIG. 5 by omitting the power supply wiring layers 31, 32, 33, and 34. Moreover, FIG. 12 is a side view diagram taken in the line A5-A5 and the line A6-A6, viewed from the direction of the arrow, in FIG. 11. FIG. 12 is a diagram depicted by superimposing a cross section taken in the line A5-A5 line on the cross section taken in the line A6-A6. By referring to FIG. 12, a connecting relationship of the equivalent circuit illustrated in FIG. 4 can be clarified.

In the standard cell SC1, as illustrated in FIG. 11, the input IN is connected to the gate electrode 11C. The signal wiring layer 401C is connected to the gate electrode 11D. The signal wiring layer 402D is connected to the signal wiring layer 405. The signal wiring layer 405 is connected to the gate electrode 11A.

Moreover, in the standard cell SC2, the signal wiring layer 401A is connected to the gate electrode 11B.

Moreover, in the standard cell SC3, the signal wiring layer 402B is connected to the gate electrode 21C. The signal wiring layer 403C is connected to the gate electrode 21A. The signal wiring layer 403A is connected to the gate electrode 21B. The signal wiring layer 403B is connected to the signal wiring layer 404. The output OUT is obtained from the signal wiring layer 404.

### (Layout Design System)

Next, a layout design system will be described for executing a layout design of the semiconductor integrated circuit 100 according to the embodiment. The semiconductor integrated circuit used for the layout design system corresponds to the semiconductor integrated circuit 100 according to the embodiment.

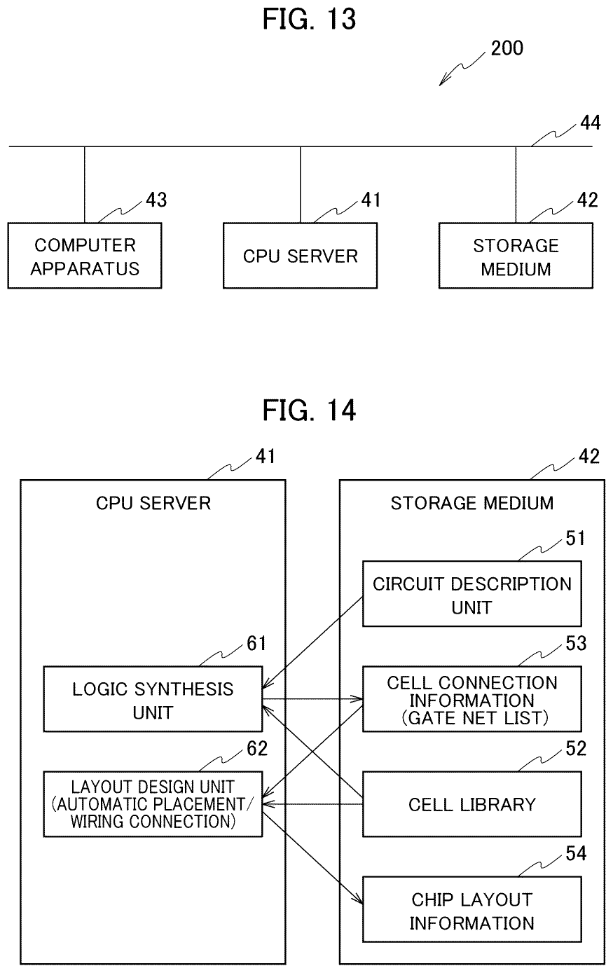

FIG. 13 is a schematic diagram illustrating a layout design system 200 for executing a layout design of the semiconductor integrated circuit according to the embodiment. FIG. 14 is a block configuration diagram illustrating the layout design system 200 illustrated in FIG. 13.

As illustrated in FIG. 13, the layout design system 200 includes a Central Processing Unit (CPU) server 41, a storage medium 42, a computer apparatus 43, and a network 44. In the following description, the central processing unit server 41 is also referred to as the CPU server 41. The CPU server 41 operates as a layout design apparatus.

In the layout design system 200, the CPU server 41, the storage medium 42, and the computer apparatus 43 operated by a user are connected to one another through the network 44. The CPU server 41 stores a computer program used for the layout design system 200. The storage medium 42 stores information and data, e.g., input information and output information required in order to execute the computer program used for the layout design system 200. The computer apparatus 43 is operated by the user and causes the CPU server 41 to execute a layout design process in accordance with the user operation.

The CPU server 41 may be, for example, an engineering workstation, a mainframe, a supercomputer, or the like. The storage medium 42 may be a non-transitory computer readable medium, such as, an external storage device such as a hard disk, a semiconductor storage device such as a memory, a storage medium. Alternatively, the storage medium 42 may be a file server or a data server. The computer apparatus 43 may be, for example, a Personal Computer (PC), a synclient terminal, a mobile terminal, a Personal Digital Assistant (PDA), or the like. The network 44 may be, for example, the Internet, intranet, Local Area Network (LAN), telephone communication networks, dedicated lines, or the like. In practice, however, it is not limited to these examples.

As illustrated in FIG. 14, the storage medium 42 includes the circuit description unit 51, the cell library 52, the cell connection information 53 (also referred to as the gate net list), and the chip layout information 54. The circuit description unit 51 is a circuit design data file described with, for example, Register Transfer Level (RTL). The circuit description unit 51 is an example of input information required for executing the computer program used for the layout design system 200.

The cell connection information 53 is a circuit design data file described with, for example, a gate level provided after the logic synthesis. The cell connection information 53 is an example of input information required for executing the computer program used for the layout design system 200.

The cell library 52 stores information on various standard cells. The standard cell information includes information on the standard cell SC1, standard cell SC2, and the standard cell SC3, that form the semiconductor integrated circuit 100 according to the embodiment. The cell library 52 is an example of input information required for executing the computer program used for the layout design system 200.

The chip layout information 54 is a circuit pattern data file for arranging the circuit on the substrate 1, for example. The chip layout information 54 is an example of output information required for executing the computer program used for the layout design system 200.

As illustrated in FIG. 14, the CPU server 41 includes a logic synthesis unit 61 and a layout design unit 62, each configured to execute the computer program used for the layout design system 200.

The logic synthesis unit 61 and the layout design unit 62 may be a processing apparatus of a CPU or microprocessor, for example. However, it is not limited to these examples.

The logic synthesis unit 61 is configured to read information stored in the circuit description unit 51 and information stored in the cell library 52 and to execute a logic synthesis of connection information on the basis of the read information. Moreover, the logic synthesis unit 61 writes the cell connection information obtained by executing the logic synthesis to the cell connection information 53 in the storage medium 42. In the present embodiment, the information logically synthesized by the logic synthesis unit 61 and stored in the cell connection information 53 is also referred to as “temporary cell connection information.”

Furthermore, the logic synthesis unit 61 calculates, with regard to each cell in the temporary cell connection information stored in the cell connection information 53, a signal delay time of a signal path including the cell, and determines whether it is possible to replace the cell with another cell (e.g., any one of the first, second, or third standard cell) having a buffer size that makes the calculated signal delay time smaller. As a result of the determination, when it is possible to replace the cell with another cell, the logic synthesis unit 61 replaces the aforementioned cell with another replaceable cell (e.g., any one of the first, second, or third standard cell).

Consequently, a cell having a relatively large capacity of the signal line to be driven is replaced with a standard cell having a relatively large capacity, and a cell having relatively small capacity of the signal line to be driven is replaced with a standard cell having a relatively small capacity. For example, a cell having a relatively large capacity of the signal line to be driven is replaced with the third standard cell SC3 which can drive the relatively large-capacity capacitor C3. In contrast, a cell having relatively small capacity of the signal line to be driven is replaced with the first standard cell SC1 or second standard cell SC2 which can drive a relatively small-capacity capacitor C1 or capacitor C2.

When the cell replacement verification process is completed for all cells included in the temporary cell connection information, the logic synthesis unit 61 stores final cell connection information in the cell connection information 53 in the storage medium 42.

More details will now be discussed hereinafter.

For example, the temporary cell connection information is formed of a cell including the first, second, or third standard cell. Alternatively, the temporary cell connection information may be formed of a cell including only the first or second standard cell. The logic synthesis unit 61 determines whether it is possible to replace, with the third standard cell, a portion that is a path having a large wiring capacity and long signal delay time but is formed of the first or second standard cell. If the replacement with a third standard cell reduces the signal delay time and meets an allowable f circuit operation, then the first and/or second standard cell in that part of the circuit is replaced with the third standard cell.

Alternatively, a portion formed of the third standard cell in spite of the relatively small wiring capacity may be replaced with the first or second standard cell. In this case, the signal delay time becomes longer. Therefore, a determination condition is that the length of the delay time is within an allowable range for circuit operation. A circuit area may be further added to the determination condition. When a circuit area exceeds a predetermined size, it is not necessary to replace the portion of the first or second standard cell with third standard cell.

The layout design unit 62 executes automatic placement and automatically wiring (routing) connection of cells on the basis of the cell connection information 53 and information of the the cell library 52, and generates chip layout information to be stored as the chip layout information 54 in the storage medium 42.

As described above, the layout design system 200 according to the embodiment is a layout design system for executing a layout design of the semiconductor integrated circuit 100, and includes a CPU server (e.g., layout design apparatus) 41 and a storage medium 42 configured to store data for the CPU server 41. The CPU server 41 includes: a logic synthesis unit 61 configured to execute a logic synthesis on the basis of information stored in the circuit description unit 51 and the cell library 52 in the storage medium 42, and to write the logically synthesized information as temporary cell connection information to the cell connection information 53 in the storage medium 42; and a layout design unit 62 configured to execute automatic placement and automatic wiring connection on the basis of the information stored in the cell connection information 53 and the cell library 52 and to generate chip layout information. The logic synthesis unit 61 calculates, with regard to each cell in the temporary cell connection information stored in the cell connection information 53, a signal delay time of a signal path including the cell, and determines whether it is possible to replace the cell with any one of the first, second, or third standard cell (SC1, SC2, or SC3) having a buffer size that makes the calculated signal delay time smaller. As a result of the determination, when it is possible to execute the replacement, the logic synthesis unit 61 replaces the cell with the replaceable first, second, or third standard cell (SC1, SC2, or SC3).

Herein, a capacity C1 of a signal line driven by the first standard cell SC1 and a capacity C2 of a signal line driven by the second standard cell SC2 is lower than a capacity C3 of a signal line driven by the third standard cell SC3.

Moreover, when a plurality of first standard cells SC1 and second standard cells SC2 are placed, at least some of the first standard cells SC1 may be placed to be stacked on at least some of the second standard cells SC2.

### (Modified Embodiment 1 of Layout Design System)

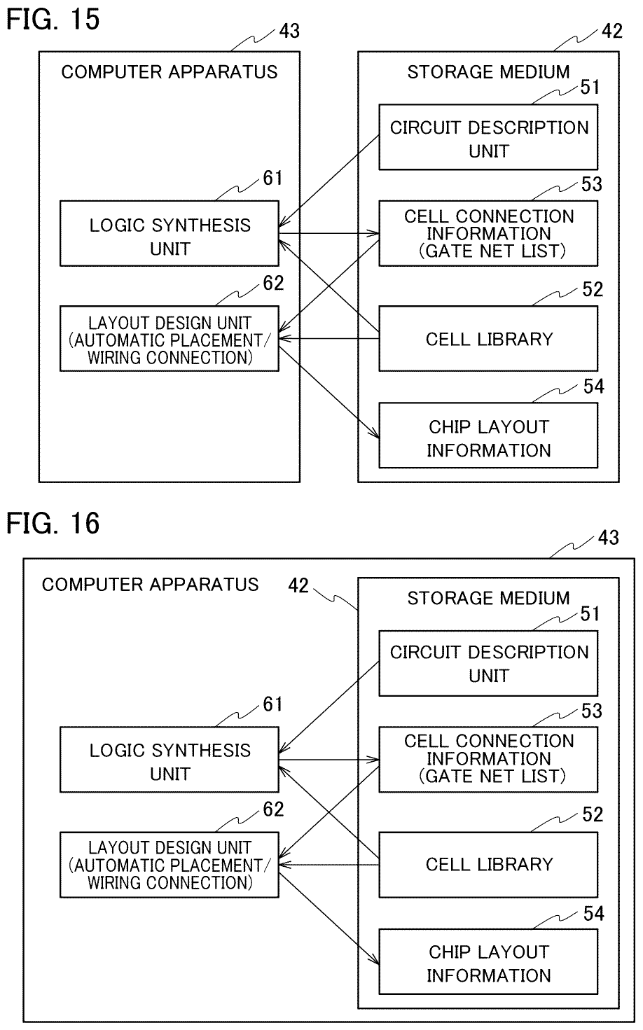

FIG. 15 is a block configuration diagram illustrating a modified embodiment 1 of the layout design system 200 illustrated in FIG. 13.

The layout design system 200 illustrated in FIG. 13 has a configuration in which the logic synthesis unit 61 and the layout design unit 62 are provided in the CPU server 41.

In contrast, in the layout design system 200 according to the modified embodiment 1, the logic synthesis unit 61 and the layout design unit 62 are provided in the computer apparatus 43 directly controlled by the user, without using the CPU server 41. Namely, in the layout design system 200 according to the modified embodiment 1, the computer apparatus 43 operates as the layout design apparatus.

The functionalities and configurations of the logic synthesis unit 61 and the layout design unit 62 provided in the computer apparatus 43 are the same as the functionalities and configurations of the logic synthesis unit 61 and the layout design unit 62 provided in the CPU server 41 in a layout design system 200 illustrated in FIG. 13.

The functionality and configuration of the storage medium 42 in the modified embodiment 1 are also the same as the functionality and configuration of the storage medium 42 in the layout design system 200 illustrated in FIG. 13.

For example, in the case of a layout design system 200 with a relatively low load, the layout design system 200 according to the modified embodiment 1 can be used.

### (Modified Embodiment 2 of Layout Design System)

FIG. 16 is a block configuration diagram illustrating a modified embodiment 2 of the layout design system 200 illustrated in FIG. 13.

In the layout design system 200 according to the modified embodiment 2, the logic synthesis unit 61 and the layout design unit 62 are provided in the computer apparatus 43 similarly to the layout design system 200 according to the modified embodiment 1 illustrated in FIG. 15, without using the CPU server 41. Namely, also in the layout design system 200 according to the modified embodiment 2, the computer apparatus 43 operates as the layout design apparatus.

Moreover, the layout design system 200 according to the modified embodiment 2 is configured so that also the storage medium 42 is provided in the computer apparatus 43. The functionalities and configurations of the logic synthesis unit 61 and the layout design unit 62 provided in the computer apparatus 43 are the same as the functionalities and configurations of the logic synthesis unit 61 and the layout design unit 62 provided in the CPU server 41 in a layout design system 200 illustrated in FIG. 13. Moreover, the functionalities and configurations thereof are also the same as the functionalities and configurations of the logic synthesis unit 61 and the layout design unit 62 provided in the computer apparatus 43 illustrated in FIG. 14. Furthermore, the functionality and configuration of the storage medium 42 provided in the computer apparatus 43 are also the same as the functionality and configuration of the storage medium 42 illustrated in FIG. 13 or 14.

For example, in the case of a layout design system 200 with a relatively low load, the layout design system 200 according to the modified embodiment 2 can be used. In accordance with the layout design system 200 according to the modified embodiment 2, the network 44 is not necessarily required.

### (Effects of Layout Design System)

As described above, in accordance with the layout design using the layout design system 200 accorded to the embodiment and the layout design systems 200 accorded to the modified embodiments 1 and 2, each cell forming the semiconductor integrated circuit 100 according to the embodiment is selectively replaced with the standard cell SC1, SC2, or SC3 in accordance with the capacity of the signal line driven by the cell, and thereby it is possible to provide the layout design system capable of efficiently executing the circuit design by utilizing multi-stacked PMOS/NMOS channels.

### (Layout Designing Method)

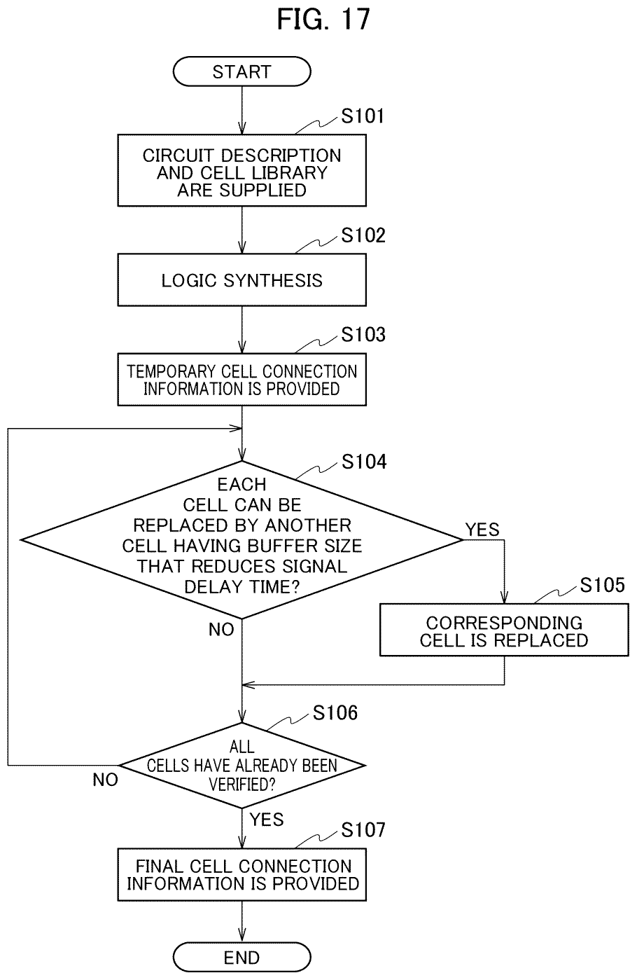

A layout designing method to which the semiconductor integrated circuit 100 according to the embodiment is applied will now be described with reference to the flow chart illustrated in FIG. 17. The layout designing method described below can be executed by the layout design system 200 according to the embodiment illustrated in FIG. 13 to 16 or the layout design systems 200 according to the modified embodiments 1 and 2.

Moreover, part or all of the layout designing method described below can also be written in a computer-executable program (e.g., computer program) as instructions for the computer to be executed. The computer program is stored in, for example, a non-transitory computer-readable storage medium to executed by the layout design system 200 according to the embodiment or the layout design systems 200 according to the modified embodiments 1 and 2.

(A) In Step S101, the logic synthesis unit 61 in the layout design system 200 reads information stored in the circuit description unit 51 and the cell library 52.

(B) In Step S102, the logic synthesis unit 61 executes a logic synthesis based on the information read from the circuit description unit 51 and the cell library 52 in the storage medium 42. Specifically, a gate net list of a desired circuit is generated from a Register-Transfer-Level (RTL) description represented by a hardware description language. The generated gate net list of the desired circuit is used as temporary cell connection information for executing the layout design of the semiconductor integrated circuit 100 according to the embodiment.

(C) In Step S103, the logic synthesis unit 61 writes the logically synthesized gate net list to the cell connection information 53 in the storage medium 42.

(D) In Step S104, the logic synthesis unit 61 calculates, with regard to each cell in the temporary cell connection information stored in the cell connection information 53, a signal delay time of a signal path including the cell, and determines whether it is possible to replace any one of the first, second, or third standard cell having a buffer size that makes the calculated signal delay time smaller.

(E) As a result of the determination, when it is possible to execute the replacement (when a result of the determination in Step S104 is YES), the logic synthesis unit 61 replaces the cell with the replaceable first, second, or third standard cell.

Through the process in Steps S104 to S105, a cell having a relatively large capacity of the signal line to be driven is replaced with a standard cell having a relatively large capacity, and a cell having relatively small capacity of the signal line to be driven is replaced with a standard cell having a relatively small capacity. For example, a cell having a relatively large capacity of the signal line to be driven is replaced with the third standard cell SC3 which can drive the relatively large-capacity capacitor C3. In contrast, a cell having relatively small capacity of the signal line to be driven is replaced with the first standard cell SC1 or second standard cell SC2 which can drive a relatively small-capacity capacitor C1 or capacitor C2.

As an example illustrated in FIGS. 1 to 4, for a certain i (where 1≤i≤N), the layout design unit 62 selectively arranges: a first standard cell SC1 in which the first conductivity type MOS as a (4i−1)^{th} layer and the second conductivity type MOS as a (4i)^{th} layer share a gate terminal; a second standard cell SC2 in which the first conductivity type MOS of a (4i−3)^{th} layer and the second conductivity type MOS as a (4i−2)^{th} layer share a gate terminal; and a third standard cell SC3 in which the first conductivity type MOSs as the (4i−3)^{th} layer and as the (4i−1)^{th} layer and the second conductivity type MOSs as the (4i)^{th} layer and as the (4i−2)^{th} layer shares a gate terminal.

Herein, a capacity C1 of a signal line driven by the first standard cell SC1 and a capacity C2 of a signal line driven by the second standard cell SC2 is lower than a capacity C3 of a signal line driven by the third standard cell SC3.

Moreover, the layout design unit 62 may execute placement and wiring, when a plurality of first standard cells SC1 and second standard cells SC2 are placed, so that at least some of the first standard cells SC1 are stacked on at least some of the second standard cells SC2.

(F) In Step S106, the logic synthesis unit 61 determines whether the cell replacement verification process has been completed for all the cells included in the temporary cell connection information stored in cell connection information 53. As a result of the determination, when all cell replacement verification processes have not been completed (i.e., when the result of the determination in Step S106 is NO), the process returns to Step S104 and the next cell is processed.

(G) As the result of the determination in Step S106, when all cell replacement verification processes have been completed (when the result of the determination in Step S106 is YES), i.e., when final cell connection information has been completed, to process proceeds to Step S107. In Step S107, the logic synthesis unit 61 writes the final cell connection information to the cell connection information 53 in the storage medium 42. The layout design unit 62 executes automatic placement and automatic wiring connection for the cell on the basis of the final cell connection information 53 and the information of the cell library 52, and generates the chip layout information. After writing the chip layout information, the process is completed.

### (Advantageous Effects of Layout Designing Method)

As described above, in accordance with the layout designing method and the computer program to which the semiconductor integrated circuit 100 according to the embodiment is applied, each cell forming the semiconductor integrated circuit 100 according to the embodiment is selectively replaced with the standard cell SC1, SC2, or SC3 in accordance with the capacity of the signal line driven by the cell, and thereby it is possible to provide the layout design system capable of efficiently executing the circuit design by utilizing multi-stacked PMOS/NMOS channels.

### Advantageous Effects of Embodiments

As described above, in accordance with the embodiments, two types of standard cells with different numbers of layers SC Type A and SC Type B are used, thereby providing a semiconductor integrated circuit with efficiently high logic density, a layout designing method, and a non-transitory computer-readable storage medium storing a program.

While certain embodiments have been described, these embodiments have been presented by way of example only, and are not intended to limit the scope of the disclosure. Indeed, the novel substrates, apparatuses, and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit comprising:
a first semiconductor layer including a first source region, a first drain region, and a first channel region;
a second semiconductor layer including a second source region, a second drain region, and a second channel region;
a gate electrode formed to cover the first channel region and the second channel region with a gate insulating film interposed therebetween; and
a first CMOS circuit and a second CMOS circuit each formed of the combination of a first conductive type MOS having the first semiconductor layer and a second conductive type MOS having the second semiconductor layer, wherein
the first semiconductor layer is stacked as a (2n−1)^{th} layer, and the second semiconductor layer is stacked as a (2n)^{th} layer (where 1≤n≤N, N≥2, and n and N are integers), wherein
for a certain i (where 1≤i≤N), in the first CMOS circuit, the gate electrode is electrically connected in common to at least the first conductive type MOS of the first semiconductor layer as a (2i−1)^{th} layer and the second conductive type MOS of the second semiconductor layer as a (2i)^{th} layer, and
in the second CMOS circuit, the gate electrode is electrically connected in common with at least the second conductive type MOS of the second semiconductor layer as the (2i)^{th} layer and the first conductive type MOS of the first semiconductor layer as a (2i+1)^{th} layer, wherein
the semiconductor integrated circuit further comprises:
for a certain i (where 1≤i≤N), a first standard cell in which the first conductivity type MOS as a (4i−1)^{th} layer and the second conductivity type MOS as a (4i)^{th} layer share a gate terminal;
a second standard cell in which the first conductivity type MOS as a (4i−3)^{th} layer and the second conductivity type MOS as a (4i−2)^{th} layer share a gate terminal; and
a third standard cell in which the first conductivity type MOSs as the (4i−3)^{th} layer and as the (4i−1)^{th} layer and the second conductivity type MOSs as the (4i)^{th} layer and as the (4i−2)^{th} layer shares a gate terminal.

2. The semiconductor integrated circuit according to claim 1, wherein
a plurality of the first standard cells and the second standard cells are provided, and at least some of the first standard cells are disposed to be stacked on at least some of the second standard cells.

3. The semiconductor integrated circuit according to claim 1, wherein
a capacity of a signal line driven by the first standard cell and the second standard cell is lower than a capacity of a signal line driven by the third standard cell.

4. The semiconductor integrated circuit according to claim 2, wherein
a capacity of a signal line driven by the first standard cell and the second standard cell is lower than a capacity of a signal line driven by the third standard cell.

5. A layout design system configured to design a layout of the semiconductor integrated circuit according to claim 1, the layout design system comprising:
a layout design apparatus; and
a storage medium configured to store data for the layout design apparatus, wherein
the layout design apparatus comprises:
a logic synthesis unit configured to execute a logic synthesis on the basis of information stored in the circuit description unit and the cell library in the storage medium, and to write the logically synthesized information as temporary cell connection information to the cell connection information in the storage medium; and
a layout design unit configured to execute automatic placement and automatic wiring connection on the basis of the information stored in the cell connection information and the cell library and to generate chip layout information, wherein
the logic synthesis unit calculates, with regard to each cell in the temporary cell connection information stored in the cell connection information, a signal delay time of a signal path including the cell, and determines whether it is possible to replace the cell with any one of the first, second, or third standard cell having a buffer size that makes the calculated signal delay time smaller, wherein
as a result of the determination, when it is possible to execute the replacement, the logic synthesis unit replaces the cell with the replaceable first, second, or third standard cell.

6. The layout design system according to claim 5, wherein
through the replacement executed by the layout design unit, a cell having a relatively large capacity of the signal line to be driven is replaced with the third standard cell, and a cell having relatively small capacity of the signal line to be driven is replaced with the first or second standard cell.

7. The layout design system according to claim 5, wherein
when a plurality of first standard cells and second standard cells are placed, the layout design unit executes placement and wiring, so that at least some of the first standard cells are stacked on at least some of the second standard cells.

8. The layout design system according to claim 6, wherein
a capacity of the signal line driven by the first standard cell and the second standard cell is lower than a capacity of the signal line driven by the third standard cell.

9. The layout design system according to claim 5, wherein
the determination of whether the replacement is possible further includes determination of whether a circuit area after the replacement is equal to or less than a predetermined size.

10. A layout designing method used for a layout design system, the layout design system configured to design a layout of the semiconductor integrated circuit according to claim 1, the layout design system comprising
a layout design apparatus, and
a storage medium configured to store data for the layout design apparatus, wherein
the layout design apparatus comprising
a logic synthesis unit configured to execute a logic synthesis on the basis of information stored in the circuit description unit and the cell library in the storage medium, and to write the logically synthesized information as temporary cell connection information to the cell connection information in the storage medium, and
a layout design unit configured to execute automatic placement and automatic wiring connection on the basis of the information stored in the cell connection information and the cell library and to generate chip layout information, wherein
the layout designing method comprising:
by the logic synthesis unit, calculating, with regard to each cell in the temporary cell connection information stored in the cell connection information, a signal delay time of a signal path including the cell, and determining whether it is possible to replace the cell with any one of the first, second, or third standard cell having a buffer size that makes the calculated signal delay time smaller; and
as a result of the determination, when it is possible to execute the replacement, replacing, by the logic synthesis unit, the cell with the replaceable first, second, or third standard cell.

11. The layout designing method according to claim 10, wherein
through the replacement executed by the logic synthesis unit, a cell having a relatively large capacity of the signal line to be driven is replaced with the third standard cell, and a cell having relatively small capacity of the signal line to be driven is replaced with the first or second standard cell.

12. The layout designing method according to claim 10, wherein
when a plurality of first standard cells and second standard cells are placed, the layout design unit executes placement and wiring, so that at least some of the first standard cells are stacked on at least some of the second standard cells.

13. The layout designing method according to claim 11, wherein
a capacity of the signal line driven by the first standard cell and the second standard cell is lower than a capacity of the signal line driven by the third standard cell.

14. The layout designing method according to claim 10, wherein
the determination of whether the replacement is possible further includes determination of whether a circuit area after the replacement is equal to or less than a predetermined size.

15. A non-transitory computer-readable medium in which a computer program is stored, the computer program being executed by a computer used for a layout design system, the layout design system configured to design a layout of the semiconductor integrated circuit according to claim 1, the layout design system comprising
a layout design apparatus, and
a storage medium configured to store data for the layout design apparatus, wherein
the layout design apparatus comprising
a logic synthesis unit configured to execute a logic synthesis on the basis of information stored in the circuit description unit and the cell library in the storage medium, and to write the logically synthesized information as temporary cell connection information to the cell connection information in the storage medium, and
a layout design unit configured to execute automatic placement and automatic wiring connection on the basis of the information stored in the cell connection information and the cell library and to generate chip layout information, wherein
the computer program comprising:
by the logic synthesis unit, calculating, with regard to each cell in the temporary cell connection information stored in the cell connection information, a signal delay time of a signal path including the cell, and determining whether it is possible to replace the cell with any one of the first, second, or third standard cell having a buffer size that makes the calculated signal delay time smaller; and
as a result of the determination, when it is possible to execute the replacement, replacing, by the logic synthesis unit, the cell with the replaceable first, second, or third standard cell.

16. The non-transitory computer-readable medium according to claim 15, wherein
through the replacement executed by the logic synthesis unit, a cell having a relatively large capacity of the signal line to be driven is replaced with the third standard cell, and a cell having relatively small capacity of the signal line to be driven is replaced with the first or second standard cell.

17. The non-transitory computer-readable medium according to claim 15, wherein
when a plurality of first standard cells and second standard cells are placed, the layout design unit executes placement and wiring, so that at least some of the first standard cells are stacked on at least some of the second standard cells.

18. The non-transitory computer-readable medium according to claim 16, wherein
a capacity of the signal line driven by the first standard cell and the second standard cell is lower than a capacity of the signal line driven by the third standard cell.

19. The non-transitory computer-readable medium according to claim 15, wherein
the determination of whether the replacement is possible further includes determination of whether a circuit area after the replacement is equal to or less than a predetermined size.
